(19) United States
(12) Patent Application Publication
(10) Pub. No.: US 2012/0206897 A1
(43) Pub. Date: Aug. 16, 2012

(54) Green electricity saver model 3000

(76) Inventors: Eric Boyer, Brighton, MA (US); John Bono, Brighton, MA (US)

(21) Appl. No.: 12/931,889

(22) Filed: Feb. 14, 2011

(51) Int. Cl. H05K 7/02

(52) U.S. Cl. 361/811

(57) ABSTRACT

A universal capacitive power factor corrector usable with single phase inductive loads encases one capacitor, of 10 microfarads, one 240 volt varistor, one 22 microhenry coil, and a 330 k ohm resistor within a housing having a power cord, on off switch, 4 amp fuse, and a indicator lamp. Overall design to correct poorly designed single phase inductive current loads for home or small business.

### BACKGROUND OF THE INVENTION

This invention relates generally to energy saving devices and more particularly concerns the reduction of electrical energy demands of smaller or moderate consumers.

More sophisticated electrical energy consumers are well aware of the impact of power factors on power demand. A low plant power factor will require an available capacity much greater then is actually used. Therefore, to avoid premium charges applied to low power factor customers, the large consumer will “correct” its overall power factor by adding to its system a load which draws the opposite kind of reactive power.

Normally, the existing reactive power is inductive, caused by motors, transformers, fluorescent lights and the like, resulting in a lagging kvar (kilovolt amperes reactive). Thus a corrective bank of capacitors is added to the system, providing a leading kvar to balance the system.

The analysis of overall system impedance to determine the corrective load needed to adjust the power factor toward unity is for the most part not within the knowledge or economic capability of the smaller or moderate consumer. As a result, they generally continue to operate at uncorrected power factor levels, drawing more current than actually needed for their load and absorbing the cost of correspondingly larger heat losses in their system.

However, perfect matching of reactive power is not necessary to achieve a savings in energy costs. Significant savings can be achieved by approximation of balancing kvar with respect to individual loads in the overall system. Approximate power factor correction of an induction motor will reduce heat losses and lengthen motor life as well as increase available capacity for other loads in the system.

Thus smaller plants, commercial facilities and even residences could benefit by application of corrective reactive loads to most machines, air conditioners and refrigeration units, pumps and the like if a single, cost effective, easily selectable, power factor corrective load were available.

### SUMMARY OF THE INVENTION

In accordance with the invention, a capacitive power factor corrector for use with single inductive loads includes a plastic box with power cord, power switch, fuse, and indicator lamp. Capacitor having capacitance value of 10 microfarads. Single phase usage of two electrical conductors are employed, one connecting power cord to fuse, switch then cap. The resistor, varistor, and lamp are all electrically connected across the two conductors. The second electrical conductor from power cord to coil then second terminal of the capacitor.

### BRIEF DESCRIPTION OF THE DRAWINGS AND OR PHOTOS

Other objects and advantages of the invention will become apparent upon reading the following detailed description and upon reference to the drawings in which:

FIG. 1 is a perspective elevational view of the empty enclosure with component holes;

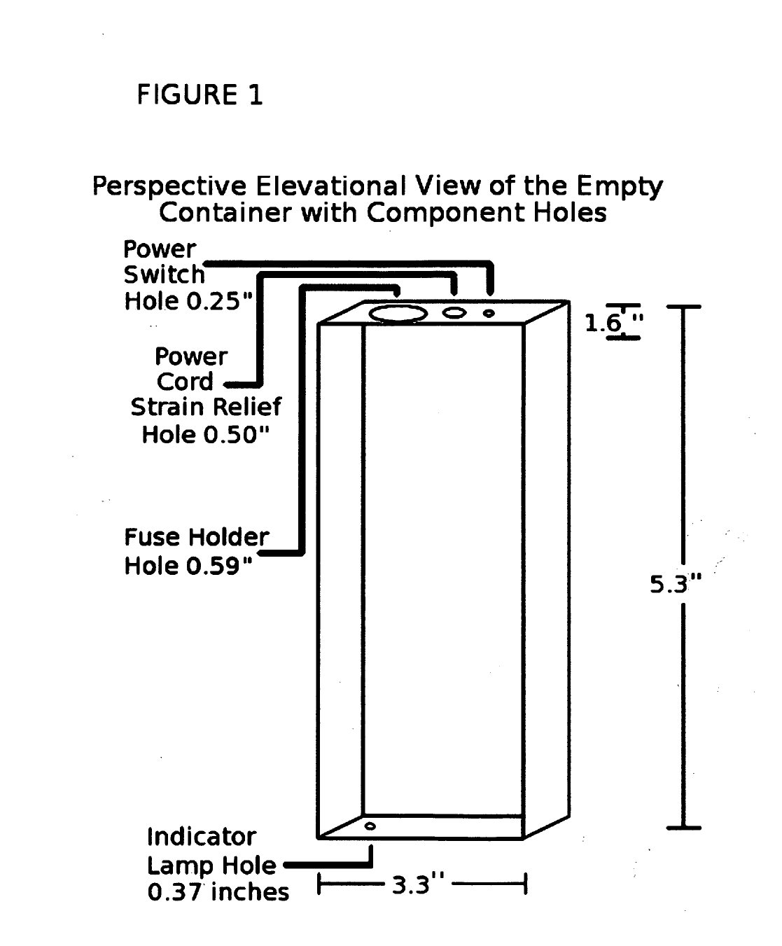

FIG. 2 is a perspective elevational view of the cover plate for use with the enclosure of FIG. 1;

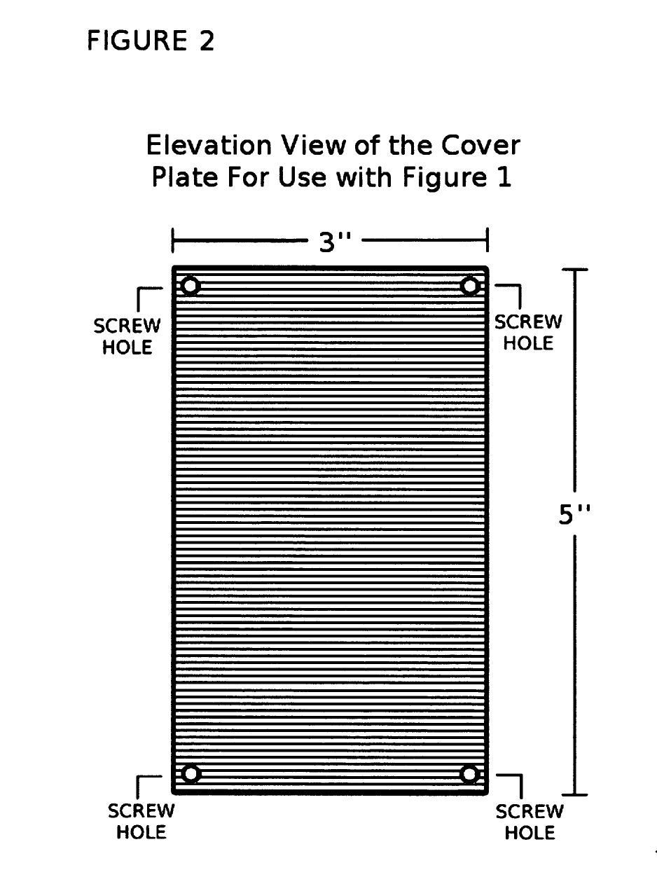

FIG. 3 screws for cover plate for use with the enclosure of FIG. 1;

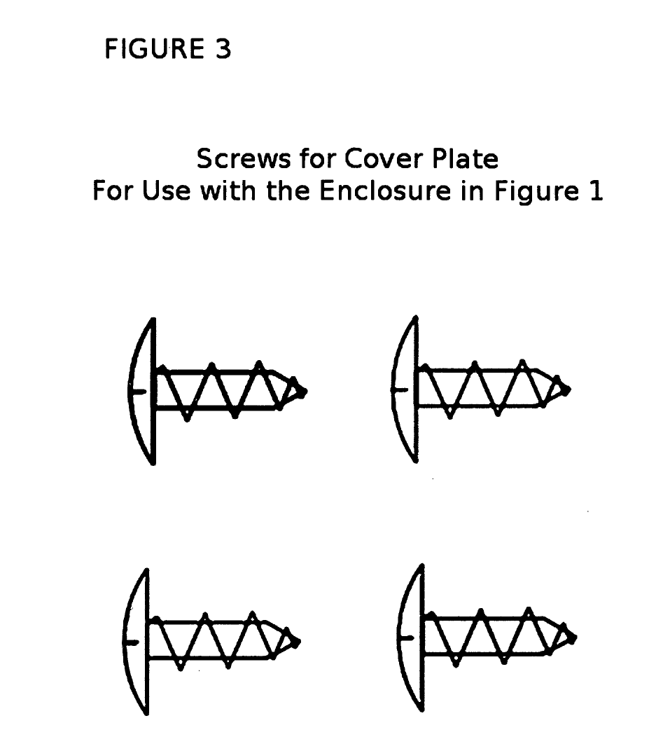

FIG. 4 is a perspective elevational view of the present invention with components and electrical connections;

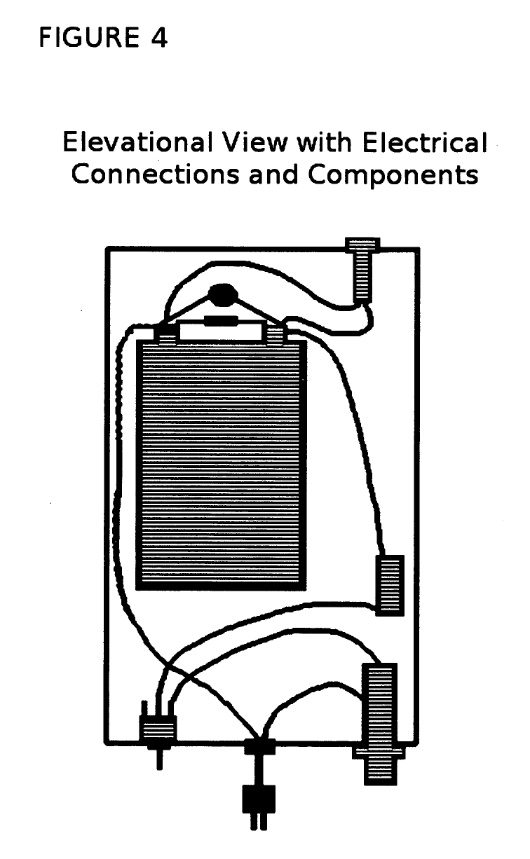

FIG. 5 is a perspective elevational view with electrical connections and components in place;

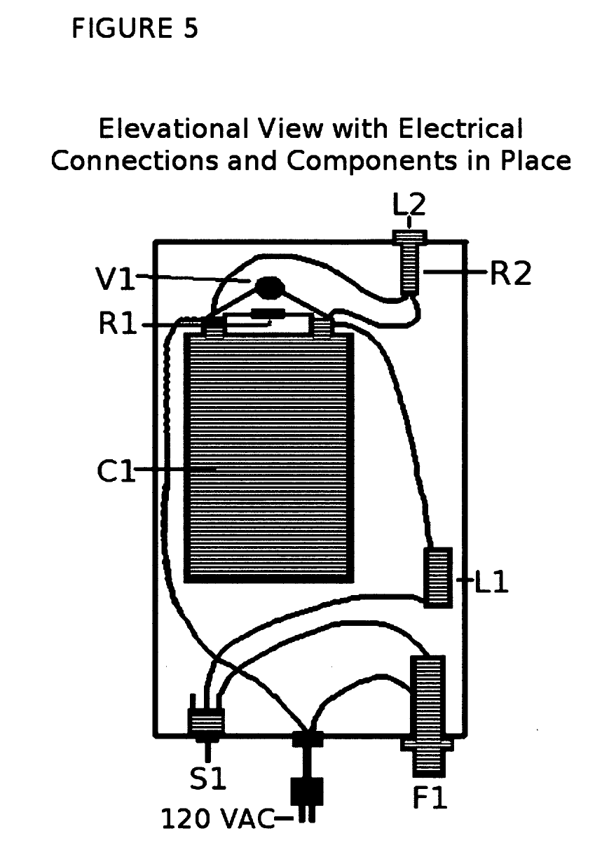

FIG. 6 schematic representation of circuit;

FIG. 7 assembled unit

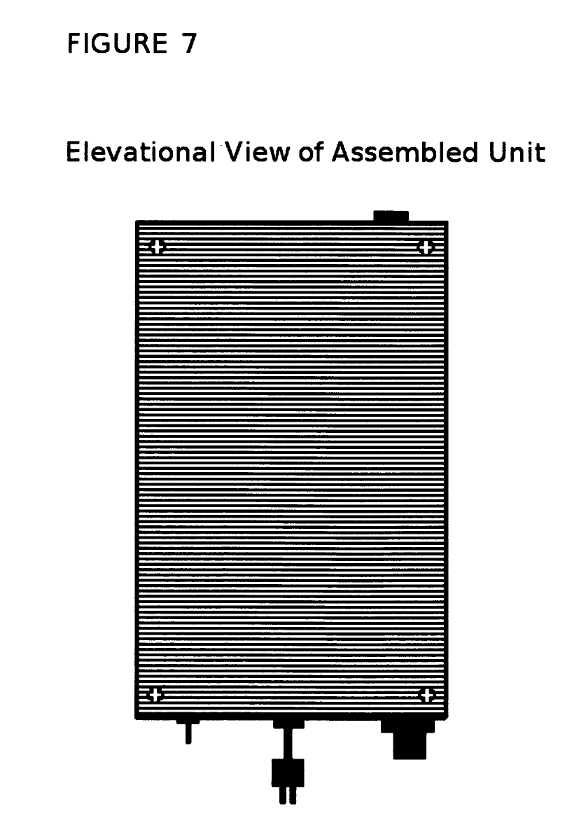

### DETAILED DESCRIPTION OF THE INVENTION

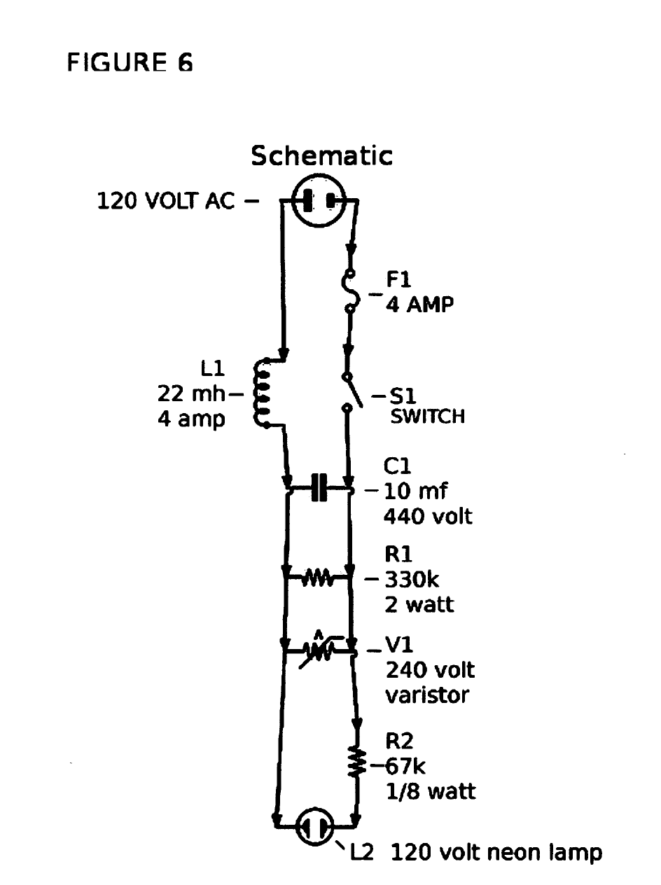

FIG. 6 schematic of circuit in detail:

List of materials with electrical values:
F1—4 amp agc fuse
S1—power switch 5 amp rated
L1—22 micro henry, coil rated 4 amps
C1—10 micro farad capacitor rated at 440 volts
R1—330 kilo ohm resistor rated at 2 watts
V1—240 volt varistor rated at 40 joules
R2—67 kilo ohm ⅛ watt resistor
L2—125 volt neon lamp

A two conductor polarized power cord-plug assembly enters the enclosure with strain relief grommet. Conductor one ties to the fuse (F1) assembly. Out of the fuse assembly conductor one enters the power switch (S1), a single pole single through toggle switch. Out of the power switch (S1) conductor one enters the 10 microfarad capacitor (C1) on terminal one of said capacitor. The second electrical conductor from power cord comes through enclosure to the 22 microhenry coil (L1) then second terminal of the 10 microfarad capacitor (C1). From terminal one of 10 microfarad capacitor Across to terminal two of the 10 microfarad capacitor (C1) we then have a 330 k ohm resistor (R1), and a 240 volt varistor (V1), and lamp assembly (L2) with two legs respectively to terminal one and two. From leg one coming into lamp assembly there is a 67 k ohm resistor (R2) to leg one of element. Leg two of element is connected directly to terminal two of capacitor (C1).

### Theoretical Explanation of Schematic:

120 volts alternating current comes into enclosure with one leg going through fuse (F1) for internal short circuit protection from source.

Next is power switch (S1) to stop electrical arc from occurring when plugging the unit into source voltage.

Then to Capacitor (C1) to hold an electrical charge to compensate for current spikes from source voltage.

120 volt leg two comes into enclosure to coil (L1) to inductively pre-load circuit output.

Then to opposite side of capacitor (C1)

Across capacitor (C1) there is a load resistor (R1) keeping the capacitor in a charging state for improved current delivery.

Across capacitor (C1) there is a 240 volt direct current rated varistor stopping alternating current voltage spikes over 120 volts smoothing source line voltage.

Across capacitor (C1) there is a neon indicator lamp assembly with resistor (R3) in series to limit current to lamp.

### Specification of User Accessible Parts and Dimensions:

### Box:

5.3″×3.3″×1.6″ H heavy-duty 3/32″ molded plastic box with aluminum cover and 4 screws.

Hole Sizes:
Switch: 0.25″ Diameter hole.
Fuse holder: 0.59″ Diameter hole.
Power cord & strain reliever: 0.50″ Diameter hole.
Lamp: 0.37″ Diameter hole.

UL Listed; Sized for the AC power cord. Recognized under Component Program of Underwriters' Laboratories File No. E-10793. Certified by Canadian Standards Assoc. File No. LR-66162. This series of AC cord bushing provides the most accepted method of securing AC power cords at the point where they enter/exit the chassis or cabinet. These bushings are generally regarded as permanent and will prevent damage to the wire as well as securing the wire against any possible in-out motion.

Molded of Nylon; the two pieces of these strain reliefs are permanently connected by an integral tether to prevent them from becoming separated.

Hole for box: 0.5″ Diameter hole.

### Switch:

6 amp @120 VAC. Solder lug terminals. ¼″-40 threaded bushing. 0.43″ long handle.

Hole for box 0.25″ Diameter hole.

### Fuse Holder:

Screw style cap. Holder fits 3 AG (AGC) or MDL fuses. Chassis mounting hole 0.59″ (15 mm) diameter. Hole for case: 0.59″ Diameter hole.

### Fuse:

Standard AGC 4 amp fuse. ¼″×1¼″

### Power Cord:

Two-conductor. 18 gauge, black SPT-1 power cord. Molded 2-prong, polarized plug. UL, CSA.

### Strain Reliever:

UL Listed; Sized for the AC power cord. Recognized under Component Program of Underwriters' Laboratories File No. E-10793. Certified by Canadian Standards Assoc. File No. LR-66162. This series of AC cord bushing provides the most accepted method of securing AC power cords at the point where they enter/exit the chassis or cabinet. These bushings are generally regarded as permanent and will prevent damage to the wire as well as securing the wire against any possible in-out motion. Molded of Nylon; the two pieces of these strain reliefs are permanently connected by an integral tether to prevent them from becoming separated. Hole for box: 0.5″ Diameter hole.

### Lamp:

Green neon indicator lamp uses a small neon bulb that has a white colored phosphor that glows a bright green when 120V to 125 VAC is applied. The neon bulb is enclosed in a see through green holder which also contains a series resistor. Hole for box: 0.37″ Diameter hole.

### CONCLUSION

Accordingly, the present invention provides a power factor correction circuit comprising a fuse, switch, a inductor, a capacitor, a resistor, and varistor to store and control AC current for home and small business usage; thereby saving energy and correcting power factor in the safest most cost effective way by current design.

As is understood by a person skilled in the art, the foregoing descriptions of the preferred embodiment of the present invention are an illustration of the present invention rather than a limitation thereof. Various modifications and similar arrangements are included within the spirit and scope of the appended claims The scope of the claims should be accorded to the broadest interpretation so as to encompass all such modifications and similar structures. While a preferred embodiment of the invention has been illustrated and described, it will be appreciated that various changes can be made therein without departing from the spirit and scope of the invention.

What is claimed is:

1. A capacitive power factor corrector for home and small business use with a single phase inductive current comprising:
A small box with a power cord, power switch, fuse and indicator lamp.
A capacitor with a capacitance value of 10 microfarads, a 22 microhenry coil, a 240 volt varistor and a 330 k ohm resistor disposed within said housing, said capacitor having first and second electrical terminals;
a first insulated conductor electrically connecting to on off switch, fuse, first terminal of capacitor; a second insulated conductor electrically connecting the coil and second terminal of capacitor; and a resistor, varistor and indicator lamp electrically connected between said first and second conductors; said first and second insulated conductors extending through plastic box to a power cord and a two prong polarized wall plug.
